(19) United States
(12) Patent Application Publication
(10) Pub. No.: US 2025/0112141 A1
(43) Pub. Date: Apr. 3, 2025

(54) QUAD FLAT NO-LEAD (QFN) PACKAGE WITHOUT LEADFRAME AND WITH LAYER OF DIELECTRIC

(71) Applicant: Deca Technologies USA, Inc., Tempe, AZ (US)

(72) Inventors: Robin Davis, Vancouver, WA (US); Paul R. Hoffman, San Diego, CA (US); Clifford Sandstrom, Richfield, MN (US); Timothy L. Olson, Phoenix, AZ (US); Benedict San Jose, City Metro Manila (PH)

(21) Appl. No.: 18/902,555

(22) Filed: Sep. 30, 2024

Related U.S. Application Data
(60) Provisional application No. 63/541,747, filed on Sep. 29, 2023.

(51) Int. Cl. H01L 23/498; H01L 21/48; H01L 23/00; H01L 23/31; H01L 25/065

(52) U.S. Cl. CPC H01L 23/49838; H01L 23/3121; H01L 23/49822; H01L 24/13; H01L 21/486; H01L 24/16; H01L 24/96; H01L 24/97; H01L 25/0655; H01L 2224/13005; H01L 2224/13147; H01L 2224/16225; H01L 2224/96; H01L 2224/97; H01L 2924/1815

(57) ABSTRACT

A QFN, DEN, SON, or LGA package without a leadframe, including a component comprising conductive studs disposed over a surface of the component, a single layer of encapsulant disposed around four side surfaces of the component and around at least a portion of the conductive studs, a layer of dielectric disposed over the single layer of encapsulant with via openings formed through the layer of dielectric, and a terminal conductive layer disposed over the layer of dielectric, the terminal conductive layer further comprising a lower surface that conformally follows contours of the layer of dielectric and the via openings, and the terminal conductive layer further comprises an upper surface having a flat surface, a slightly domed surface, a slightly concave surface or an upper surface that is flatter than the lower surface.

### RELATED APPLICATIONS

This application claims the benefit of U.S. provisional patent application 63/541,747, filed on Sep. 29, 2023, titled “Quad Flat No-Lead (QFN) Package without Leadframe and with Layer of Dielectric” the entirety of the disclosure of which is hereby incorporated by this reference.

### TECHNICAL FIELD

This document relates to devices and methods of forming QFN, dual flat no-lead (DFN) or small-outline no-lead (SON) semiconductor packaging without a leadframe, with interconnect structures having molded direct contact interconnect build-up layers and dielectric layers. The packages may further comprise LGA pads or a terminal metal or terminal layer comprising a flat surface.

### BACKGROUND

Semiconductor devices, packages, substrates, and interposers are commonly found in modern electronic products. Production of semiconductor devices involves a multistep build-up of components. Conventional interconnect structures alternate dielectric and conductive layers. An opening, via, and capture pads, may be created to allow connectivity from one conductive layer to another between dielectric layers. Conventional capture pads formed as part of the conductive layers are required to correct for misalignment of the vias in manufacture. Use of conventional capture pads impacts the ability to construct compact structures due to limits on routing density. Additionally, traditional manufacturing processes for the aforementioned package types often involves the use of leadframes.

### SUMMARY

An opportunity exists for improved semiconductor assemblies, including applications for semiconductor manufacturing. Accordingly, in some embodiments, a QFN, DFN, SON, or LFA package without a leadframe, comprising a component comprising conductive studs disposed over an active layer of the component. A single layer of encapsulant may be disposed around four side surfaces of the component, disposed over the active layer of the component, and contacting at least a portion of sidewalls of the conductive studs. A flat surface, comprising a flat encapsulant surface and exposed ends of the conductive studs, may be disposed over the active layer of the component and around a periphery of the exposed ends. An internal conductive layer may be disposed over the flat surface and configured to be electrically coupled with the conductive studs to fan-out from the component. A layer of dielectric may be disposed over the flat surface and the internal conductive layer. Via openings may be formed through the layer of dielectric that extend to the internal conductive layer. A flag and land grid array (LGA) pads may be formed as part of a terminal conductive layer disposed over the layer of dielectric. The flag and LGA pads extend through the via openings and contact the internal conductive layer. An upper surface of the flag may be at a same level as an upper surface of the LGA pads.

In some aspects, the flag and the LGA pads may each comprise a lower surface that is curved to conformally follow contours of the layer of dielectric and the via openings. The terminal conductive layer may further comprise an upper surface that is flatter than the lower surface. The upper surfaces of the flag and the LGA pads may comprise a flatness with a peak to valley distance of less than half a thickness of a maximum thickness of the dielectric layer. The upper surface of the terminal conductive layer may comprise less than or equal to 10 μm of height difference over an entire horizontal distance. Thermal studs may be disposed between, and be coupled to, the component and the flag. The conductive stud may comprise a sidewall angle in a range of 80-90° and the via openings may comprise a sidewall angle in a range of 70-89°. A position of the LGA pad may be determined with unit-specific patterning such that an outline of LGA pad aligns more closely to an outline of the package than to an outline of the component. The internal conductive layer may be disposed over the flat surface and configured to be electrically coupled with the conductive studs to fan-out from the component. An upper surface of the terminal conductive layer may comprise a flat surface, a slightly domed surface, or a slightly concave surface. A vertical offset of the upper surface of the terminal conductive layer may vary plus or minus 5-10% of a thickness of the terminal conductive layer. The LGA pads may comprise a non-spherical in form.

In other embodiments, a QFN, DFN, SON, or LGA package without a leadframe may comprise a component comprising conductive studs disposed over a surface of the component. A single layer of encapsulant may be disposed around four side surfaces of the component and around at least a portion of the conductive studs. A layer of dielectric may be disposed over the single layer of encapsulant with via openings formed through the layer of dielectric. A terminal conductive layer may be disposed over the layer of dielectric, the terminal conductive layer further comprising a lower surface that conformally follows contours of the layer of dielectric and the via openings. The terminal conductive layer may further comprise an upper surface that is flatter than the lower surface.

In some aspects, the terminal conductive layer may further comprise LGA pads. The terminal conductive layer may further comprise a flag with an upper surface at a same level as an upper surface of the LGA pads. The conductive studs may comprise a sidewall angle that is substantially vertical and a via formed in the via openings may comprise a sidewall angle less than the sidewall angle of the conductive stud. The single layer of encapsulant may be a material suitable for planarizing, such as with grinding or chemical mechanical planarizing (CMP). A position of the LGA pads may be determined with unit-specific patterning such that an outline of the LGA pads aligns more closely to an outline of the package than to an outline of the component. The upper surface of the terminal conductive layer may comprise a flat surface, a slightly domed surface, or a slightly concave surface. A vertical offset of the upper surface of the terminal conductive layer may vary by plus or minus 5-10% of a thickness of the terminal conductive layer. The upper surface of the flag and the LGA pads may be nonconformal with respect to the layer of dielectric, an internal conductive layer, and the via openings.

The foregoing and other aspects, features, and advantages will be apparent from the description and drawings, and from the claims. Unless specifically noted, it is intended that the words and phrases in the specification and the claims be given their plain, ordinary, and accustomed meaning to those of ordinary skill in the applicable arts. The inventors are fully aware that they can be their own lexicographer if desired. The inventors expressly elect, as their own lexicographers, to use only the plain and ordinary meaning of terms in the specification and claims unless they clearly state otherwise and then further, expressly set forth the “special” definition of that term and explain how it differs from the plain and ordinary meaning. Absent such clear statements of intent to apply a “special” definition, it is the inventors' intent and desire that the simple, plain and ordinary meaning to the terms be applied to the interpretation of the specification and claims.

The inventors are also aware of the normal precepts of English grammar. Thus, if a noun, term, or phrase is intended to be further characterized, specified, or narrowed in some way, then such noun, term, or phrase will expressly include additional adjectives, descriptive terms, or other modifiers in accordance with the normal precepts of English grammar. Absent the use of such adjectives, descriptive terms, or modifiers, it is the intent that such nouns, terms, or phrases be given their plain, and ordinary English meaning to those skilled in the applicable arts as set forth above.

Further, the inventors are fully informed of the standards and application of the special provisions of 35 U.S.C. § 112 (f). Thus, the use of the words “function,” “means” or “step” in the Detailed Description or Description of the Drawings or claims is not intended to somehow indicate a desire to invoke the special provisions of 35 U.S.C. § 112 (f), to define the invention. To the contrary, if the provisions of 35 U.S.C. § 112 (f) are sought to be invoked to define the inventions, the claims will specifically and expressly state the exact phrases “means for” or “step for”, and will also recite the word “function” (i.e., will state “means for performing the function of [insert function]”), without also reciting in such phrases any structure, material or act in support of the function. Thus, even when the claims recite a “means for performing the function of . . . ” or “step for performing the function of . . . ,” if the claims also recite any structure, material or acts in support of that means or step, or that perform the recited function, then it is the clear intention of the inventors not to invoke the provisions of 35 U.S.C. § 112 (f). Moreover, even if the provisions of 35 U.S.C. § 112 (f) are invoked to define the claimed aspects, it is intended that these aspects not be limited only to the specific structure, material or acts that are described in the preferred embodiments, but in addition, include any and all structures, materials or acts that perform the claimed function as described in alternative embodiments or forms of the disclosure, or that are well known present or later-developed, equivalent structures, material or acts for performing the claimed function.

### BRIEF DESCRIPTION OF THE DRAWINGS

Implementations will hereinafter be described in conjunction with the appended and/or included drawings, where like designations denote like elements.

FIG. 1A is a representation of a plan view of a semiconductor wafer or native wafer with a base substrate material.

FIGS. 1B-1F illustrate a non-limiting process of thinning and dicing a semiconductor wafer on which conductive studs have already been formed.

FIG. 2A illustrates components and molded components disposed over temporary carrier having encapsulant disposed thereon to form a panel or reconstituted panel.

FIG. 2B illustrates a cross-sectional view of the panel or reconstituted panel having molded components disposed therein, taken along the section line shown in FIG. 2A.

FIG. 2C depicts a cross-sectional profile view illustrating a conductive layer being formed over a flat surface of the panel.

FIG. 2D is another cross-sectional profile view illustrating a layer of dielectric material disposed over the conductive layer.

FIG. 3A illustrates a conductive layer formed as a flag and conductive pads over the dielectric material.

FIG. 3B illustrates the section view of 3A, depicting the conductive layer having a conformal upper surface and extending through a via in the dielectric material.

FIG. 3C illustrates a QFN, DFN, SON, or LGA package comprising conductive pads and flag formed with dimples in the upper surfaces.

FIG. 4A shows a cross-sectional profile similar to the view of FIG. 3A illustrating a conductive layer formed as a flag and conductive pads over the dielectric material;

FIG. 4B illustrates the section view of FIG. 4A, depicting the conductive layer having a flat upper surface and extending through a via in the dielectric material.

FIG. 4C is a cross-sectional perspective view illustrating a QFN, DFN, SON, or LGA package comprising conductive pads and a flag formed with flat upper surfaces and thermal studs coupled to a component and the flag.

FIG. 4D, similar to FIG. 4C, is a cross-sectional perspective view that illustrates a QFN, DEN, SON, or LGA package in which the package is formed without thermal studs.

FIG. 5A is another cross-sectional profile similar to the views of FIGS. 3A and 4A.

FIG. 5B, continuing from FIG. 5A, is a close-up or enlarged view taken along the section line 5B illustrating the section view of 5A, depicting the conductive layer having a slightly convex upper surface and extending through a via in the dielectric material.

FIG. 5C, continuing from FIG. 5A, is a cross-sectional perspective view illustrating a QFN, DEN, SON, or LGA package comprising conductive pads and flag formed with convex upper surfaces.

FIG. 6A is a cross-sectional profile similar to the views of FIGS. 3A, 4A and 5A, showing a conductive layer formed as a flag and conductive pads over the dielectric material.

FIG. 6B illustrates the section view of FIG. 6A, depicting the conductive layer having a slightly concave upper surface and extending through a via in the dielectric material.

FIG. 6C is a cross-sectional perspective view illustrating a QFN, DFN, SON, or LGA package comprising conductive pads and a flag formed with slightly concave upper surfaces and thermal studs coupled to a component and the flag.

FIGS. 7A and 7B illustrate the QFN, DEN, SON, or LGA package comprising LGA pads 82 formed as multi-row LGA pads or an array of LGA pads.

FIG. 8A illustrates a QFN, DEN, SON, or LGA package comprising a multi-layer stack with a first internal conductive layer disposed over an encapsulant.

FIG. 8B illustrates another embodiment of the package of FIG. 8A comprising a multi-layer stack where a layer of dielectric is formed between the first internal conductive layer and the encapsulant.

FIG. 8C illustrates the section view of FIG. 8B depicting additional detail of the multi-layer stack showing the dielectric as formed between the first internal conductive layer and the encapsulant and vias through the dielectric.

FIG. 8D illustrates a QFN, DEN, SON, or LGA package or assembly comprising a multi-layer stack in a sandwich configuration with upper and lower dielectric layers 70, and one or more layers of encapsulant 42 disposed therebetween.

FIG. 8E illustrates the electronic assembly or package of FIG. 8D comprising a multi-layer stack in another sandwich configuration, with upper and lower encapsulant layers 42, with one or more dielectric layers 70 disposed therebetween.

FIG. 8F illustrates a detail view of the electronic assembly of FIG. 8E comprising a multi-layer stack and relative sidewall angles for vias disposed in encapsulant and dielectric materials.

FIG. 9 illustrates a QFN, DEN, SON, or LGA package is formed using unit-specific patterning (also known under the tradename Adaptive Patterning™) such that a position and outline of the flag aligns more closely to an outline of the package than to an outline of the component.

### DETAILED DESCRIPTION

The disclosure includes one or more aspects or embodiments in the following description with reference to the figures, in which like numerals represent the same or similar elements. Those skilled in the art will appreciate that the description is intended to cover alternatives, modifications, and equivalents as may be included within the spirit and scope of the disclosure as defined by the appended claims and their equivalents as supported by the following disclosure and drawings. In the description, numerous specific details are set forth, such as specific configurations, compositions, and processes, etc., in order to provide a thorough understanding of the disclosure. In other instances, well-known processes and manufacturing techniques have not been described in particular detail in order to not unnecessarily obscure the disclosure. Furthermore, the various embodiments shown in the FIGS. are illustrative representations and are not necessarily drawn to scale.

The disclosure, its aspects and implementations, are not limited to the specific package types, material types, or other system component examples, or methods disclosed herein. Many additional components, manufacturing and assembly procedures known in the art consistent with semiconductor wafer fabrication, manufacture and packaging are contemplated for use with particular implementations from this disclosure. Accordingly, for example, although particular implementations are disclosed, such implementations and implementing components may comprise any components, models, types, materials, versions, quantities, or the like as is known in the art for such systems and implementing components, consistent with the intended operation.

The word “exemplary,” “example” or various forms thereof are used herein to mean serving as an example, instance, or illustration. Any aspect or design described herein as “exemplary” or as an “example” is not necessarily to be construed as preferred or advantageous over other aspects or designs. Furthermore, examples are provided solely for purposes of clarity and understanding and are not meant to limit or restrict the disclosed subject matter or relevant portions of this disclosure in any manner. It is to be appreciated that a myriad of additional or alternate examples of varying scope could have been presented but have been omitted for purposes of brevity.

The foregoing and other aspects, features, and advantages will be apparent from the description and drawings, and from the claims if any are included.

The disclosure relates to a QFN, DEN, SON, or LGA package without a leadframe and with molded direct contact interconnect build-up structures, and a method of making the same. A QFN, DEN or SON is a small-sized integrated circuit (IC) package that offers small size, low cost, and very good electrical and thermal performance. Conventional QFN packages often comprise side lengths of about, or on the order of 5 mm. Conventional QFN, DFN and SON packages typically include a leadframe which is integrated into the package. The use of a leadframe can result in exposed copper at the singulated edges of the packages which often solders poorly, preventing solder fillets from forming. The lack of solder fillets around the edge of the packages poses issues, such as inhibiting recognition by automated optical inspection (AOI) tools, and the reduced solder footprint of the package creates a reliability risk, limiting end-use applications. The disclosure herein concerns QFN, DFN and SON packages formed without a leadframe.

Conventionally QFN, DFN, and SON packages may be understood to comprise packages with pads around the periphery and without pads at a center of the packages. As used herein, the terms QFN, DEN, SON, or LGA are used to reference new and improved packages that improve upon conventional packages. As such, the POSA will appreciate that the improvements described herein apply equally to: (i) structures that comprise packages with pads around the periphery and without pads at a center of the packages, as well as to (ii) packages that comprise pads at a center of the package, as well as to (iii) pads LGA pads, or a terminal structure that is in any desirable configuration or arrangement, such as to accommodate any configuration of pins or IO.

As used herein, “about” and “substantially” mean the stated amount plus or minus (+/−) 50% or less, 40% or less, 30% or less, 20% or less, 10% or less, 5% or less, or 1% or less. Those of ordinary skill in the art are familiar with QFN, DEN, SON, and LGA package structures.

No-lead packages such as QFN, DFN, SON, and LGA package packages physically and electrically connect to the surface of printed circuit boards (PCB's) or other substrates using surface mount technology, thus coupling the IC to the PCB or other substrate. The present disclosure relates to QFN, DFN, SON, and LGA packages without a leadframe, and with molded direct contact interconnect build-up structures. An example of a molded direct contact interconnect build-up structure is known under the trademark or tradename MDx™. Molded direct contact interconnect build-up structures (and a method for making and using the same) are discussed in: (i) U.S. patent application Ser. No. 18/195,090 titled “Molded Direct Contact Interconnect Structure without Capture Pads and Method for the Same,” filed May 9, 2023; and (ii) U.S. patent application Ser. No. 18/225,064 titled “Molded Direct Contact Interconnect Substrate” filed Jul. 21, 2023; and (iii) U.S. patent application Ser. No. 17/957,683, titled “Quad Flat No-Lead (QFN) Package without Leadframe and Direct Contact Interconnect Build-Up Structure and Method for Making the Same,” filed Sep. 20, 2022, the entirety of each of which is hereby incorporated herein by reference. Molded direct contact interconnect build-up structures may comprise or provide: (i) large area chip bond pad interconnect to create a very low contact resistance, (ii) removal of capture pads between build-up layers, such as traces, (iii) cost savings by removing polyimide and other polymers from the build-up layers, using mold compound instead, and (iv) facilitate ultra-high-density connections such as 20 micrometer bond pitch and smaller.

At least some of the above advantages are available at least in part by using unit specific patterning (such as adaptive patterning (custom design and lithography) and build-up interconnect structures such as a frontside build-up interconnect structure, which is also known under the trademark “Adaptive Patterning,” referred to as “AP.” Unit specific patterning: (i) allows for the use high-speed chip attach for semiconductor chips and AP will ensure alignment for high density interconnects with the molded direct contact interconnect build-up structures. Adaptive Patterning may also be used in the herein disclosed processes for manufacturing QFN, DEN, SON, and LGA packages including the ability to make large area connections which are precisely aligned to chip bond pads for very low contact resistance.

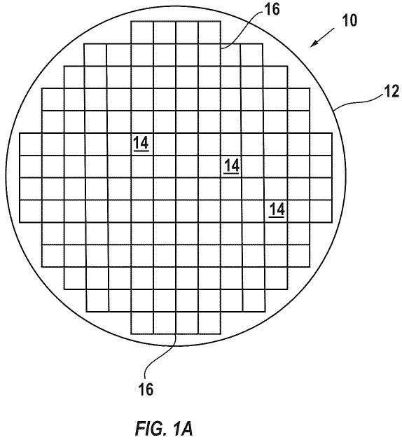

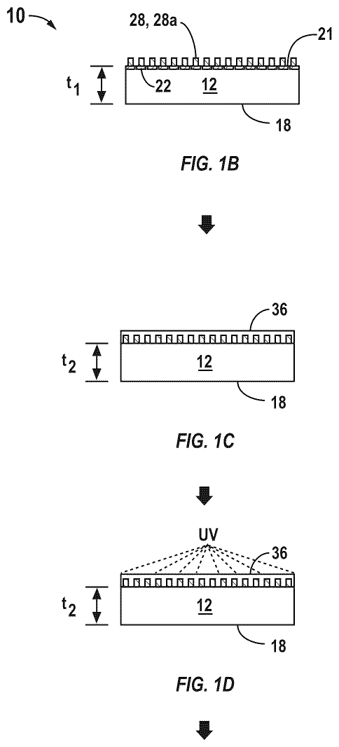

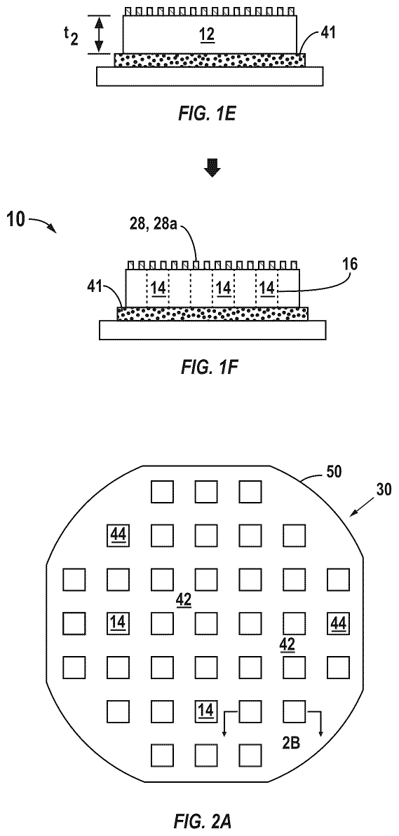

FIG. 1A shows a plan view of a semiconductor wafer or native wafer 10 with a base substrate material 12, such as, without limitation, silicon, germanium, gallium arsenide, indium phosphide, or silicon carbide, for structural support. A plurality of chips, semiconductor die, or components 14 can be formed on wafer 10 separated by a non-active, inter-die wafer area or saw street 16. As used herein, the component 14 comprises active devices, passive devices, or both. Components 14 comprise semiconductor components, chips, and semiconductor die. Components 14 further comprise non-semiconductor components such as components that are non-active, or are formed without transistors. Components 14 comprise sensors and microelectromechanical systems (MEMS) that do not rely on semiconductor materials for making transistors. Components 14 also comprise discrete passives such as resistors or capacitors, other semiconductor die, ICs, bridge die, wafer level chip scale packages (WLCSPs), MEMs and any other suitable component. For purposes of illustration, a non-limiting example of the component 14 being a chip or semiconductor die is described in FIGS. 1A-1F. Accordingly, the saw street 16 can provide cutting areas to singulate the semiconductor wafer 10 into the individual components or chips 14.

Each chip 14 may comprise a backside or back surface 18 and an active surface or active layer 20 opposite the backside 18. The active layer contains one or more analog, passive, or digital circuits implemented as active devices, passive devices, or simply conductive layers, and dielectric layers formed within the die area and electrically interconnected according to the desired electrical function or design. For example, the circuit may include one or more transistors, diodes, and other circuit elements formed within the active layer to implement analog circuits or digital circuits, such as DSP, ASIC, memory, or other circuits. The semiconductor chip may also contain integrated passive devices (IPDs) such as inductors, capacitors, and resistors, for RF signal processing. The semiconductor chip may also contain only electrical interconnect functionality such as, but not limited to, a bridge die. The chips 14 may be formed on a native wafer in a wafer level process as one of many chips or die being formed simultaneously on the wafer, as shown e.g., in FIG. 1A.

Each semiconductor chip or component 14 may comprise a backside or back surface and an active layer opposite the backside. The active layer contains one or more circuits or discrete components of any kind implemented as active devices, or only conductive layers, and dielectric layers formed within or on the chip and electrically interconnected according to the electrical design and function of the semiconductor chip. For example, the circuit may include, without limitation, one or more transistors, diodes, and other circuit elements formed within active layer to implement analog circuits or digital circuits, such as DSP, ASIC, memory, or other signal processing circuits. The semiconductor chip may also contain IPDs such as inductors, capacitors, and resistors, for RF signal processing, digital power line control or other functions. The semiconductor chip 14 may consist only of conductive routing layers and associated dielectric layers such as for use as a bridge chip between active devices or other electrical function. The semiconductor chip 14 may also be added as one of many chips being added simultaneously on a carrier. The semiconductor chip may also be only a dummy substrate with no electrical function, but rather act merely as a structural element. In some instances, there can be connections on both sides of the chip. The principles and structures taught in relation to this disclosure are applicable to known existing technologies that are compatible with the QFN, DEN, SON, or LGA packages disclosed without a leadframe and using direct contact interconnect build-up.

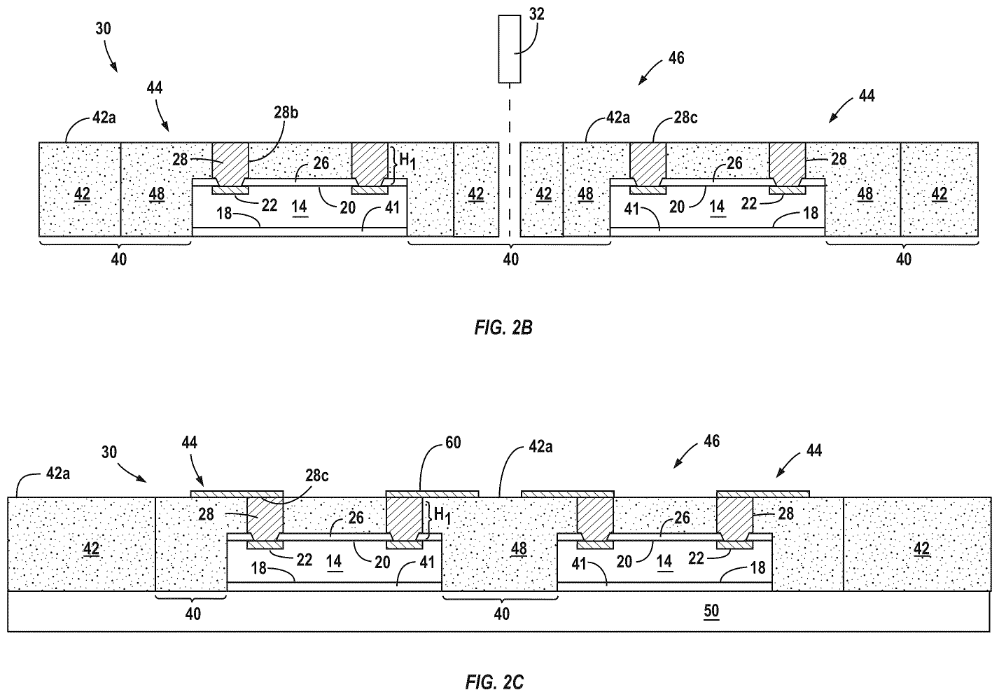

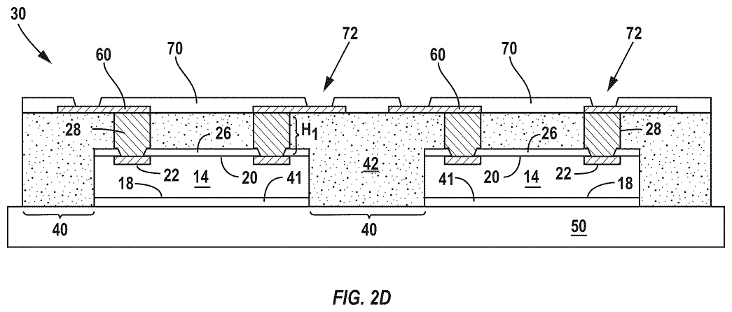

FIGS. 1B-1F illustrate a non-limiting process or flow of thinning and dicing a semiconductor wafer 10 into components 14, on which conductive (e.g., copper) studs, stumps, bumps or interconnects 28 have been formed over an active layer 20 of each of the components 14. In some embodiments, conductive studs 28 may comprise thermal studs 28a as subsequently described. FIG. 1B illustrates an incoming full thickness (as shown by t1) semiconductor wafer 10 comprising base substrate material 12 with Cu Studs 28 formed over active layer 20 having a height in the range of 5-50 um Cu Stud height. According to FIG. 1C, backgrind tape 36 may be laminated to the surface or active layer 20 of wafer 10 and backgrinding may be performed to a reduced thickness (as shown by t2), such as within a range from 50 to 650 μm thickness. FIG. 1D illustrates where a UV treatment of the backgrind tape 36 may be used to facilitate easier removal of the backgrind tape 36 from backside 18. As shown by FIG. 1E, a 2:1 tape mount, where the wafer 10 is coupled to a saw tape which may or may not include a die attach film (DAF) 41, may be done by mounting opposite the conductive studs 28, and the backgrind tape 36 is removed from over the copper studs 28, and FIG. 1F depicts a saw, cut, or dicing of the wafer 10 along saw streets 16 to form components 14. Wafer expansion and separation of the chips, semiconductor die, or components 14 may be performed such that after expansion of the die attach film 41, the chips, semiconductor die, or components 14 are then ready for die attach, such as by a pick and place to remove them from the DAF 41 and attach them to a temporary carrier 50, as shown in FIG. 2A.

FIG. 2A illustrates a temporary carrier, a reusable carrier, a sacrificial carrier, or any suitable carrier 50, made of metal, glass, silicon, mold compound, or other suitable material, with a release layer. The temporary carrier 50 may comprise a form factor or footprint of a wafer (circular footprint), a panel (square or rectangle), or of any suitable shape and may comprise a diameter or width of 200-600 mm, such as 300 mm, or of any other suitable size.

As illustrated in FIG. 2A, components 14 may be disposed over temporary carrier 50 using a pick and place operation, or in any other suitable way. In some embodiments, the method of making the QFN, DEN, SON, or LGA packages comprises disposing at least two components 14, such as semiconductor components, face-up on the temporary carrier 50, where face-up means the conductive studs 28 are disposed in a direction opposite the temporary carrier 50. An encapsulant 42 can be disposed around the components 14, including over at least 5 sides of components 14, such as around 4 sides surfaces and over a surface or active layer 20 or over a backside 18. The encapsulant 42 can be deposited around the plurality of components 14 using a paste printing, compression molding, transfer molding, liquid encapsulant molding, lamination, vacuum lamination, spin coating, or other suitable application method. The encapsulant 42 can be a polymer composite material, such as epoxy resin with filler commonly referred to as molding compound, epoxy acrylate with filler, or other polymer with proper filler. According to some embodiments, components 14 can be embedded together in component encapsulant 48 (as shown in FIG. 2B), to form a molded component 44 which is thereafter disposed over temporary carrier 50 using a pick and place operation similar to as done for components 14 (as shown in FIG. 2A). The encapsulant 42 can also be disposed around molded components 44, and contacting component encapsulant 48, in a similar manner as components 14 to form reconstituted panel 30. Reconstituted panel 30 may comprise any combination of components 14 and molded components 44. The encapsulant 42 and component encapsulant 48 can be non-conductive and environmentally protect the components 14 from external elements and contaminants. While the disclosure refers to components 14 for simplicity and ease of description, a person of ordinary skill in the art (a POSA) will appreciate that molded components 44 could be included in a similar manner for all embodiments of assemblies or packages 110 and the related methods as disclosed herein. Accordingly, components 14 and molded components 44 are referred to collectively hereinafter as components 14.

The orientation of components 14, can be either face up with active layer 20 oriented away from carrier 50 to which the components 14 are mounted, or alternatively can be mounted face down with active layer 20 oriented toward the carrier 50 to which the components 14 are mounted. Accordingly, an adhesive or die attach film (DAF) 41 (see, e.g., FIG. 1D) can be included or omitted from over back surface 18 of components 14, depending on the process used for encapsulating the components 14 and forming a panel or reconstituted panel 30 comprising components 14 fully molded in a core of encapsulant 42 or within an epoxy core.

The panel 30 can optionally undergo a curing process to cure encapsulant 42. A surface of encapsulant 42 can be substantially coplanar with adhesive 41. Alternatively, encapsulant 42 can be substantially coplanar with backside 18, the encapsulant being exposed by the removal of carrier and interface layer. The panel 30 can include a footprint or form factor of any shape and size including circular, rectangular, or square, such as a form factor in a range of 200-600 millimeters (mm), including that of a semiconductor wafer including a circular footprint having a diameter of 300 mm. Any other desirable size can also be formed.

FIG. 2B illustrates a cross-sectional view of the reconstituted wafer or reconstituted panel 30, taken along the section line 2B shown in FIG. 2A. FIG. 2B shows a molded component 44 comprising a component 14 which comprises conductive studs 28 disposed over an active layer 20 of a component 14 being singulated from the panel 30. The molded component 44 may comprise a single layer of a component encapsulant 48 disposed around four side surfaces of the component 14, disposed over the active layer of the component, and around and contacting at least a portion of sidewalls 28b of the conductive studs 28. Where reconstituted panel 30 comprises at least one molded component 44, a single layer of encapsulant 42 may be disposed around at least four surfaces of the molded component 44 and may in some embodiments be disposed over a top or bottom surface of the molded component 44. In some embodiments, encapsulant 42 may comprise a same or similar material as component encapsulant 48. While FIG. 2B depicts molded component 44 with one component 14, FIG. 2C illustrates molded component 44 comprising two components 14. A person of skill in the art would understand that molded component 44 may comprise one, two or more components 14.

Each component 14 is shown comprising a backside or back surface 18 and an active layer 20 (also shown in FIG. 1B) opposite the backside 18. However, as noted above, in some instances the component 14 may not comprise an active layer 20.

An electrically conductive layer or contact pads 22 is formed over active layer 20 using PVD, CVD, electrolytic plating, electroless plating process, or other suitable metal deposition process. Conductive layer 22 can be one or more layers of aluminum (Al), Titanium (Ti), copper (Cu), tin (Sn), nickel (Ni), gold (Au), palladium (Pd), silver (Ag), cobalt (Co), platinum (Pt), or other suitable electrically conductive material. Conductive layer 22 operates as contact pads or bond pads electrically coupled or connected to the circuits on active layer 20. Conductive layer 22 can be formed as contact pads disposed side-by-side a first distance from an edge of component 14, as shown in FIG. 2B. Alternatively, conductive layer 22 can be formed as contact pads that are offset in multiple rows such that a first row of contact pads is disposed a first distance from the edge of the component 14, and a second row of contact pads alternating with the first row is disposed a second distance from the edge 24 of the component 14. In other instances, the component 14 can comprise digital chips, analog chips, or RF chips (or other chips) with more than two rows of bond pads, and may further comprise bond pads 22 over the whole surface of the chip that do not follow a full grid pattern. Other components 14 may have bond pads in an array over the whole surface of the chip.

FIG. 2B further shows one or more optional insulating, passivating, or dielectric layer 26 may be conformally applied over active layer 20 and over conductive layer 22. Insulating layer 26 can include one or more layers that are applied using PVD, CVD, screen printing, spin coating, spray coating, sintering, thermal oxidation, or other suitable process. Insulating layer 26 can contain, without limitation, one or more layers of silicon dioxide (SiO₂), silicon nitride (Si₃N₄), silicon oxynitride (SiON), tantalum pentoxide (Ta₂O₅), aluminum oxide (Al₂O₃), polymer, polyimide, benzocyclobutene (BCB), polybenzoxazoles (PBO), or other material having suitable insulating and structural properties. Alternatively, component 14 are packaged without the use of insulating layer 26. In another embodiment, insulating layer 26 includes a passivation layer formed over active layer 20 without being disposed over conductive layer 22. When insulating layer 26 is present and formed over conductive layer 22, openings are formed completely through insulating layer 26 to expose at least a portion of conductive layer 22 for subsequent mechanical and electrical interconnection. Alternatively, when insulating layer 26 is omitted, conductive layer 22 is exposed for subsequent electrical interconnection without the formation of openings.

FIG. 2B shows conductive studs, conductive stumps, or electrical interconnect structures 28 can be formed as conductive studs, bumps, thick pads, columns, pillars, posts, or conductive studs and are disposed over, and coupled or connected to, contact pads 22. The conductive studs 28 can be formed directly on contact pads 22 using patterning and metal deposition processes such as printing, PVD, CVD, sputtering, electrolytic plating, electroless plating, evaporation, or other suitable metal deposition process. Alternately, conductive studs 28 may be formed in a position not vertically over the pads 22 and connected by RDL. Conductive studs 28 can be one or more layers of Al, Cu, Sn, Ni, Au, Ag, palladium (Pd), or other suitable electrically conductive material and can include one or more UBM layers. In an embodiment, a photoresist layer can be deposited over component 14 and contact pads 22. A portion of the photoresist layer can be exposed and removed by a developing or other suitable process. Electrically conductive studs 28 can then be formed as pillars or other structures as previously described in the removed portion of the photoresist and over contact pads 22 using a plating process. In some embodiments, copper may be used in a plating process. The photoresist layer and other appropriate layers, such as the seed layer, can be removed leaving conductive studs 28 that provide for subsequent mechanical and electrical interconnection and a standoff with respect to active layer 20 and insulating layer 26 if present. In some instances, the conductive studs 28 may comprise a height, H1, (as shown in FIG. 2B) in a range of 10-100 micrometers (μm), 5-50 μm, or about 25 μm.

A conductive stud 28 is a conductive interconnect structure that may have generally vertical sides and may be wider than it is tall, built-up on a substrate, such as over an active surface of a component, over polyimide, or over mold compound. A conductive stud, though typically formed of the same materials as a pillar or post would be formed, may differ from a pillar or post, each of which may have a height greater than its width. A conductive stud, though it is commonly formed in a cylindrical shape, may be formed with a cross-sectional area that is circular, oval, octagonal, or as any polygonal or other shape and size. Another use for a conductive stud is as a dummy thermal conductive stud that is not electrically coupled to an active electrical circuit but is instead thermally coupled to a heat source of an active device to conduct and/or dissipate the heat to another structure, such as to a die pad on a surface of the component 14. The generally vertical sides of a conductive stud 28 are different from the sides shape that exists for a solder ball or a compressed or outwardly deformed solder ball that has generally rounded sides. The generally vertical nature of a conductive stud 28 comes from being formed in a structure that has been previously developed or etched, such as within openings in a photoresist layer, which will also be generally vertical, although it may comprise imperfections or irregularities in shape that result from the etching process, the photoresist material, or other materials and processes used. For example, developing or etching does not generally perfectly or uniformly remove the photoresist within the openings, and therefore forms imperfect, generally vertical openings for deposition of conductive materials for the conductive stud 28. The term “generally vertical” as used herein includes substantially vertical, perfectly vertical, and imperfectly vertical sides. A conductive stud is not a wire bond and is not solder.

Still referring to FIG. 2B, the reconstituted panel 30 can undergo an optional grinding, polishing or planarizing operation on the layer of encapsulant 42 (or component encapsulant 48) over the active layer 20 of the components 14 to reduce the thickness of the panel 30 and to create a planarized, flat surface 46. The flat surface 46 may comprise a planarized, flat encapsulant surface 42a (comprising at least one of the component encapsulant 48 and the encapsulant 42) and planarized, exposed ends 28c of the conductive studs 28. According to some embodiments, the flat encapsulant surface 42a may be disposed around a periphery of the exposed ends 28c of the conductive studs 28. A chemical or plasma etch can also be used to remove any residual conductive material from the planarized portion 42a of encapsulants 42 and 48 in panel 30. Thus, the exposed ends 28c of conductive studs 28 can be exposed with respect to encapsulants 42 and 48 at the flat surface 46 of panel 30 to provide for electrical connection between components 14 and a subsequently formed interconnect layer or redistribution layer.

The panel 30 can be singulated through panel gaps or saw streets 40 using a saw blade, grinding wheel, plasma cutting tool, laser cutting or other suitable tool 32 into individual molded components or molded semiconductor devices 44. The molded components 44 can then be used as part of a subsequently formed assembly or package 110 as discussed in greater detail below. However, the molded component 44 comprising at least one component or semiconductor die or other component can also be fully testable after conductive studs 28 are applied and before the molded components 44 are singulated from panel 30 or assembled into another structure. In other instances, panel 30 will singulated at a later time and after subsequent processing, such as after the formation of other structures to create a QFN, DEN, SON, or LGA package as described with respect to subsequent FIGS.

In some instances, the molded semiconductor component 44 can be formed as described in U.S. patent application Ser. No. 13/632,062, now U.S. Pat. No. 8,535,978, entitled “Die Up Fully Molded Fan-out Wafer Level Packaging,” which was filed on Apr. 29, 2015, the entirety of the disclosure of which is incorporated herein by this reference.

FIG. 2C, continuing from FIG. 2B, is a cross-sectional profile view illustrating forming a conductive layer, an internal conductive layer, or first conductive layer 60 over, and in some cases in direct contact with, the flat surface 46 of the panel 30. The conductive layer 60 may comprise a redistribution layer (RDL) or fan-out RDLs, and may be formed over the encapsulant 42, over the component encapsulant 48, or disposed over other intervening insulating or dielectric layers (such as polyimide (PI) or other suitable material), placed over, and in contact with, the encapsulant 42, and in some embodiments comprising a molded component 44, in direct contact with the component encapsulant 48. In some embodiments, the conductive layer 60 may comprise an internal or first conductive layer and may be configured to be electrically coupled with the conductive studs 28 of a component 14 or a molded component 44 through flat or planarized ends 28c to fan-out from the component 14 or molded component 44. Conductive layer 60 may be formed using a patterning and metal deposition process such as printing, PVD, CVD, sputtering, electrolytic plating, electroless plating, metal evaporation, metal sputtering, or other suitable metal deposition process. Conductive layer 60 can be one or more layers of Al, Cu, Sn, Ni, Au, Ag, or other suitable electrically conductive material. Conductive layer 60 provides an electrical path between conductive studs 28 and a subsequently formed conductive layer, terminal conductive layer, or external conductive layer 80, that may comprise conductive pads or LGA pads 82, flag 84, and other desirable structures. Conductive layer 60 may according to some embodiments be referred to as a terminal conductive layer in the sense that it provides a terminal or connection point to other structures or io connections or with objects outside of package or electronic assembly 110. Portions of conductive layer 60 can be electrically common or electrically isolated depending on the design and function of the package or assembly 110.

FIG. 2D, continuing from FIG. 2C, is another cross-sectional profile view of an embodiment where panel 30 comprises at least two components 14 comprising conductive studs 28 disposed over a surface such as an active surface 20 of the component 14. FIG. 2D, similar to the depiction of molded component 44 in FIG. 2B, illustrates disposing a layer of encapsulant 42 in a single step around four side surfaces of the components 14, over active surfaces 20 of the components 14, and around the conductive studs 28, such as around and contacting at least a portion of sidewalls 28b of the conductive studs 28. The single layer of encapsulant 42, in some embodiments further including component encapsulant 48, may be a material suitable for planarizing, such as with grinding or chemical mechanical planarizing (CMP).

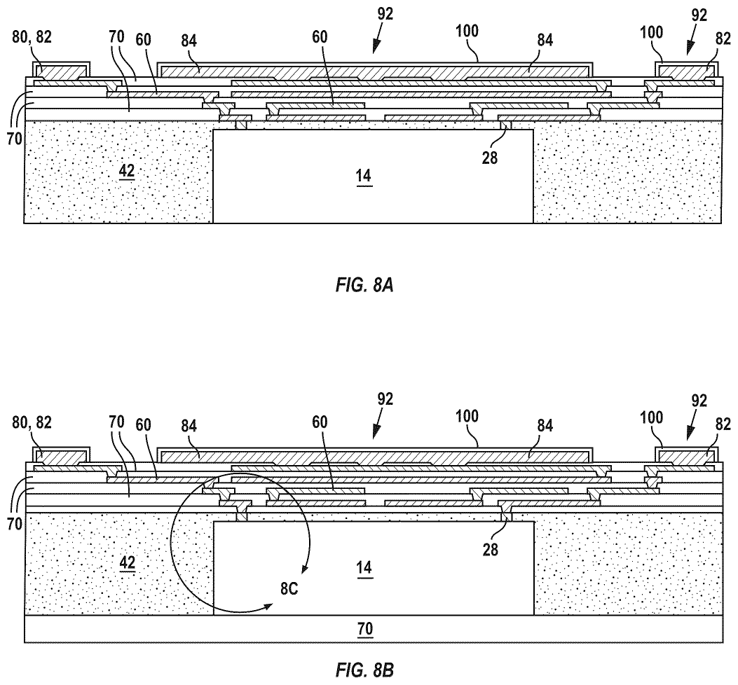

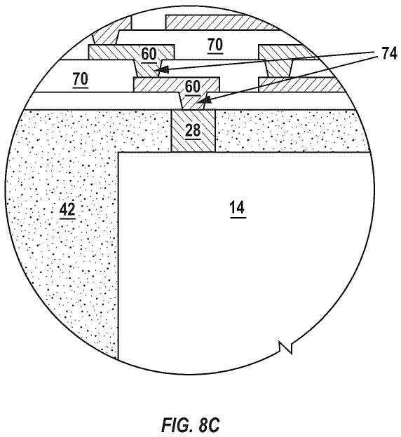

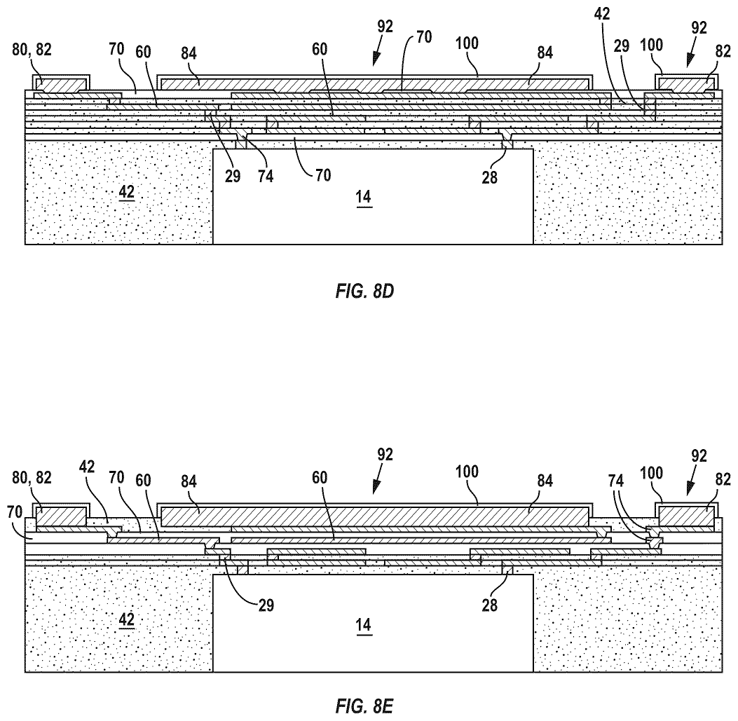

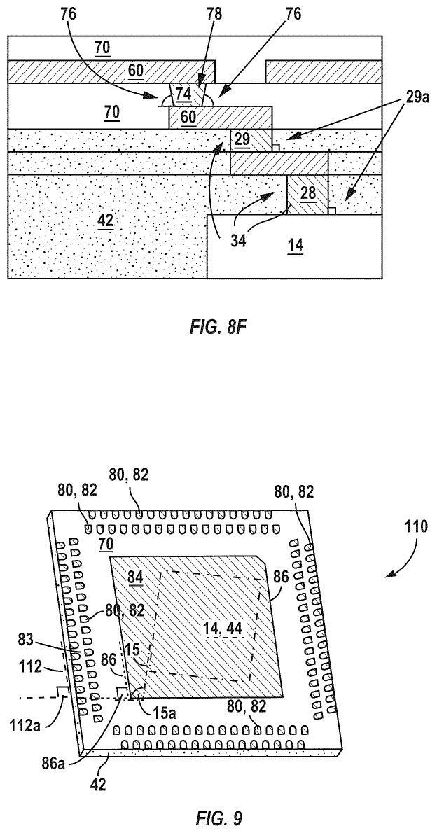

FIG. 2D depicts disposing a layer of dielectric 70 over the flat surface 46 of the layer of encapsulant 42 and over the first conductive layer 60, with openings or via openings 72 formed in dielectric 70 for subsequent formation of vias 74 (as shown in FIG. 8C) disposed through the layer of dielectric 70. In the case of a molded component 44 (as shown in FIGS. 2B and 2C), the dielectric 70 may also be disposed over the flat surface 46 of component encapsulant 48 and over the first conductive layer 60. The layer of dielectric 70 electrically insulates the first conductive layer 60 from any subsequently formed conductive layers. The layer of dielectric 70 may comprise photoimageable polyimide (PI), solder mask, image sensor resist, epoxy molded sheet, Ajinomoto Build Up Film (ABF), screen printed epoxy paste, slot die coated, or spin coated liquid epoxy. These materials allow the layer of dielectric 70 to be patterned to form via openings 72 for subsequent deposition of vias 74. The layer of dielectric 70 may be made of polyimide, polymer, solder mask, epoxy, epoxy molded sheet, screen printed epoxy paste, liquid epoxy resin, image sensor resist, or ABF. Using these materials provides good electrical insulation. The layer of dielectric 70 may be disposed by lamination, molding, slot die coating, or spin coating. These processes allow the dielectric layer 70 to conformally coat over the encapsulant 42 and first conductive layer 60. The purpose and function of the dielectric layer 70 is to insulate the first conductive layer 60. The dielectric layer 70 is disposed over the flat surface 46, comprising the flat encapsulant surface 42a of encapsulants 42 and 48, and over the first conductive layer 60.

Openings or via openings 72 may be formed through the layer of dielectric 70 extending to and exposing portions of the conductive layer 60 or the conductive studs 28. Via openings 72 are formed through the layer of dielectric 70 to expose the first conductive layer 60. The via openings 72 provide openings in the dielectric layer 70 that allow electrical connections to be made through the dielectric layer 70 to the first conductive layer 60 below. The via openings 72 may be formed through the dielectric layer 70 using a photoimageable process, plasma etching process, or a laser ablation process. These processes allow the via openings 72 to be precisely defined in the dielectric layer 70. In some instances, a photoimageable process exposes and develops the dielectric material in the desired via pattern. In other instances, a laser ablation or plasma etching process may selectively remove the dielectric material to form the via openings 72. Dielectric layer 70 may comprise a maximum thickness, tmax, in a range of from about 1 μm to about 10 μm, from about 2 μm to about 7 μm or from about 2 μm to about 4 μm.

The via openings 72 comprise sidewalls that define the openings in the dielectric layer 70. As shown in FIG. 8F, according to a via last structure 78, the sidewalls of the via openings 72 have a sidewall angle 76 less than the sidewall angles 29a of the conductive studs 28 or conductive stumps 29 according to a via first structure 34.

A “via last” structure 78 represents where a via opening 72 is first formed in the dielectric 70, then a conductive material, such as copper, a copper alloy or other conductive material, is subsequently formed or deposited into the opening, thereby forming via 74 to provide electrical coupling between conductive layers 60 and similar first or conductive layers 60 and terminal conductive layers 80. In other words, the via is formed after the dielectric 70 or supporting material is formed.

A “via first” structure 34 represents where a conductive or thermal stud 28, 28a or a conductive stump 29 has been formed over an active layer 20 of the component 14 or formed over flat surface 46 of encapsulant 42, and encapsulant 42 may be subsequently disposed around sidewalls 28b of the conductive studs 28 or thermal studs 28a, and around conductive stumps 29. Accordingly, the conductive studs 28, thermal studs 28a and conductive stumps 29 may have substantially vertical sidewalls with a sidewall angle 29a of 80-90 degrees, whereas the vias 74 formed within via openings 72 of dielectric 70 can have a sidewall angle 76 of 70-89 degrees. This allows the vias 74 of the via last structure to be wider at the top surface of the dielectric layer 70 and more narrow at the bottom surface. Thus, the conductive and thermal studs 28, 28a and conductive stumps 29 may comprise a sidewall angle 29a, as part of a via first structure or process 34, that is substantially vertical, while the via 74, as part of the via last structure 78, may comprise a sidewall angle 76 which is less than the sidewall angle 29a of the conductive studs 28 or stumps, 29.

The layer of dielectric 70 provides a manufacturable process and less expensive way to insulate and protect the first conductive layer 60 compared to using a second thin layer of encapsulant 42. The layer of dielectric 70 allows for patterning via openings 72 and vias 74 through known, low-cost methods like photoimaging, laser ablation, or other suitable processes, while being a less expensive material and process than molding or placing encapsulant 42. Overall, the layer of dielectric 70 may reduce costs by utilizing a less expensive, and manufacturable materials that are optimized for patterning vias 74.

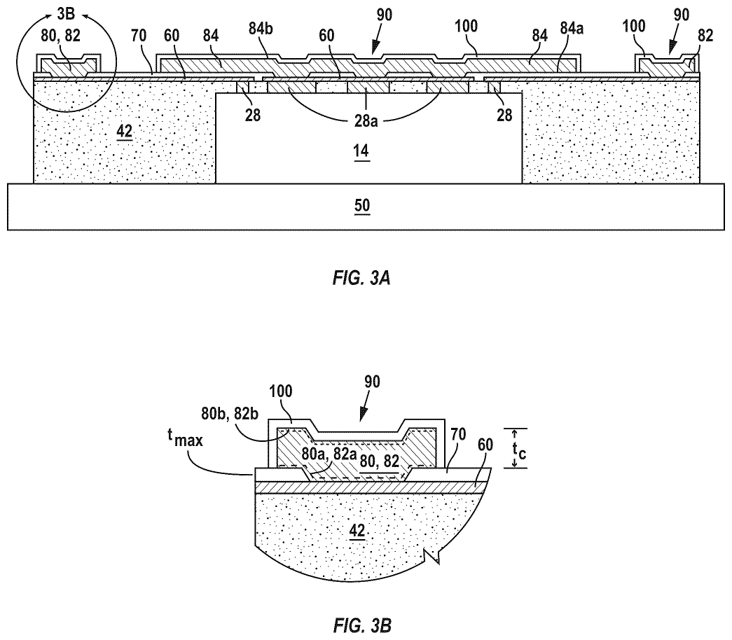

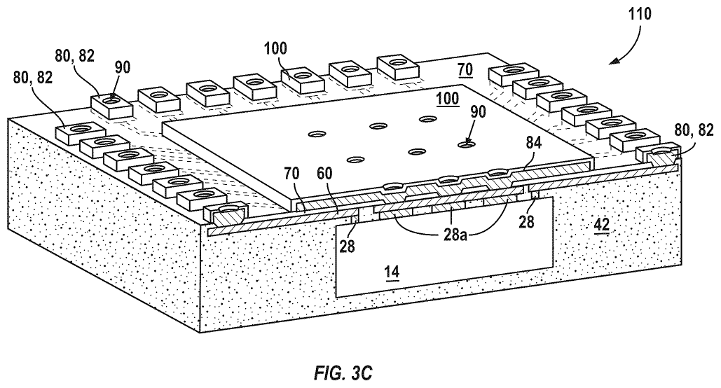

FIG. 3A, continuing from FIG. 2D, is a cross-sectional profile view illustrating the layer of dielectric material 70 disposed over the conductive layer 60, with openings or via openings 72 formed completely through the dielectric layer 70 to expose portions of the conductive layer 60. FIG. 3A further illustrates forming a second conductive layer or terminal conductive layer 80 in the form of a flag 84 and forming conductive pads of the terminal conductive layer 80 as land grid array (LGA) pads or bumps 82 that extend through the via openings 72 and contact the first conductive layer 60.

The flag 84, the LGA pads 82, or other conductive features may be formed conformally over the dielectric layer 70 with standard Cu plating chemistry, such as with electroplating or electroless plating, resulting in conformal plating and a conformal structure of surfaces of the LGA pads 82 and flag 84. Conformal, conformal plating, a conformal structure or conformal deposition refers to a deposit or structure having a substantially uniform thickness across a width or horizontal distance (as depicted in FIG. 3B). For example, one or more (including all) of the conductive or terminal conductive layer 80, the conductive LGA pads 82, and the conductive flag 84, comprise contours that follow the downward slope and sidewall angles 76 of the vias 74, and result in a depression or a dimple 90 in the conductive layer or terminal conductive layer 80, and therefore a dimple 90 may be present in either or both of the conductive LGA pads 82, and the conductive flag 84 formed therefrom, in locations above the via last structure 78. Such depression or dimple 90 may result in air bubbles being trapped during solder reflow as part of surface mount technology (SMT) processing to connect the package 110 to a PCB, interposer or other substrate, creating a weaker and less robust structure or bond, reducing one or more of strength, durability, and yield.

According to some embodiments, the second conductive layer 80 may be formed as a terminal conductive layer 80 over the layer of dielectric 70. The second conductive layer 80 may comprise conductive pads 82 formed as land grid array (LGA) pads or bumps, and a flag 84. The conductive pads or land grid array (LGA) pads 82 and flag 84 extend through the via openings 72 to contact the first conductive layer 60. This electrically connects the pads 82 and flag 84 to the first conductive layer 60. The conductive pads 82 and flag 84 may be formed by electroplating using a plating bath with additives including at least one of a leveler, suppressor, and accelerator.

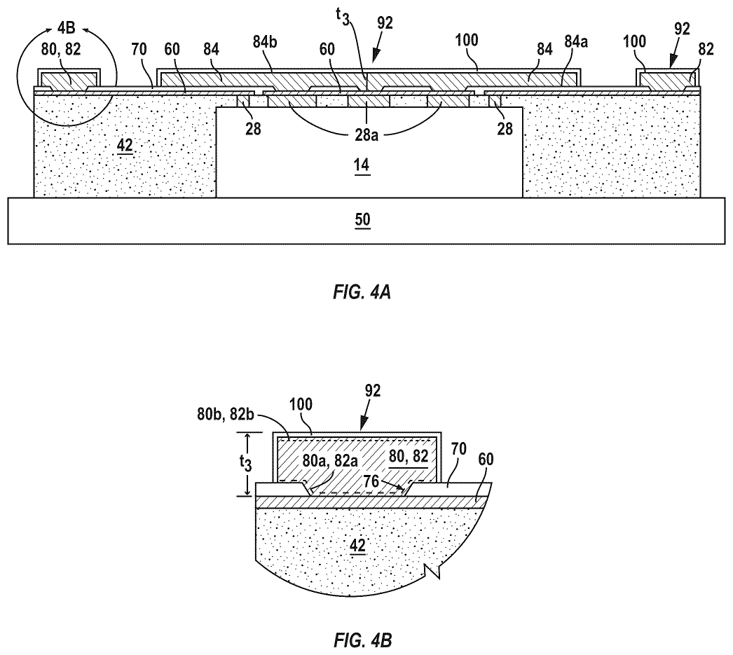

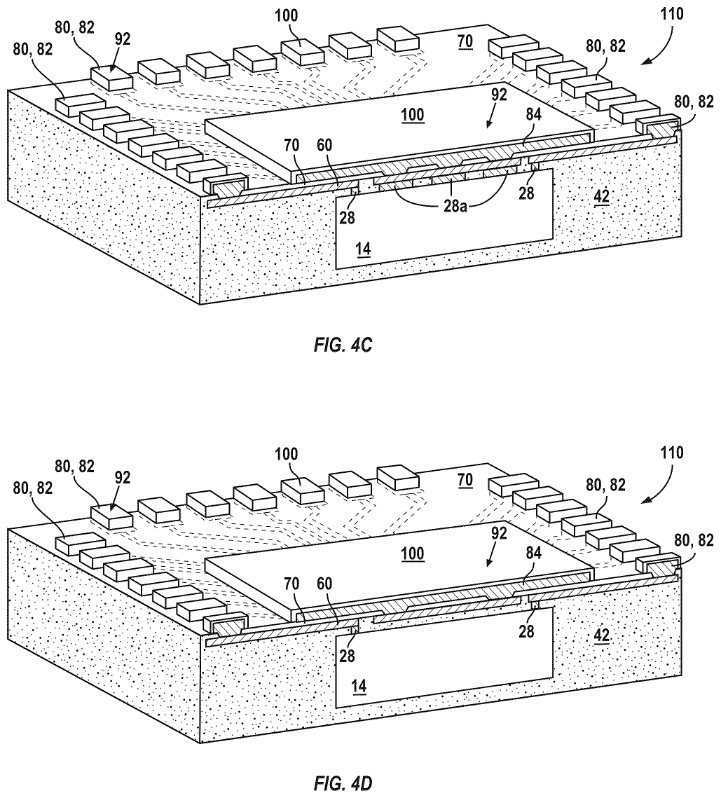

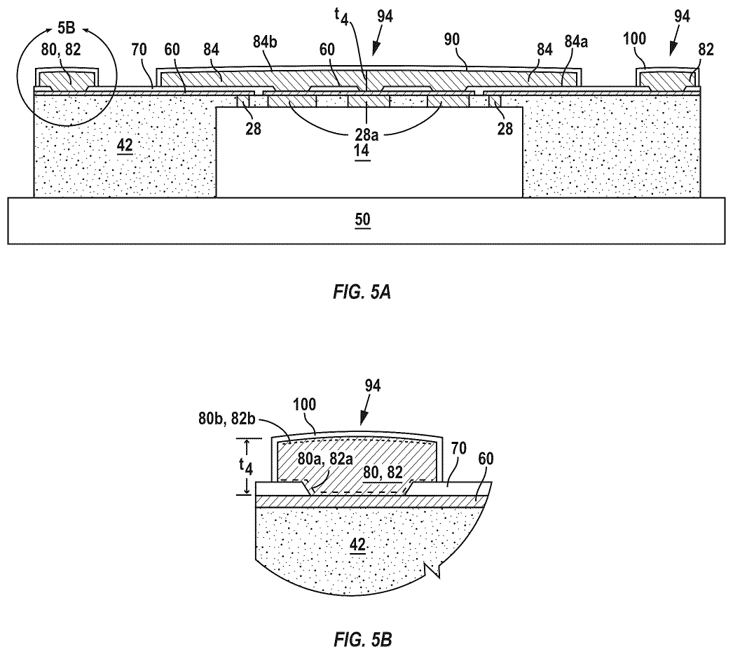

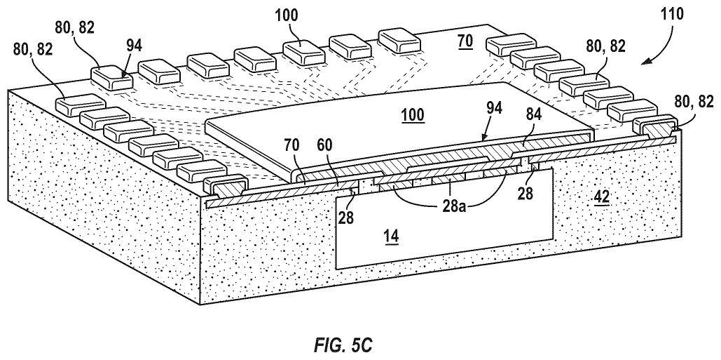

The upper surface 80b of the terminal conductive layer 80 may comprise any of a flat surface 92 (as seen in FIGS. 4A-4D), a slightly domed or a convex surface 94 (as seen in FIGS. 5A-5C), and a slightly concave surface 96. Similarly, the upper surfaces 82b and 84b of the LGA pads and flag, respectively, may comprise any of a flat surface 92, a slightly domed or a convex surface 94 and a slightly concave surface 96. When conventional, standard high volume manufacturing (HVM) plating processes are used, the upper surfaces 80b, 82b and 84b of the terminal conductive layer 80, the LGA pads and the flag, respectively, are typically conformally deposited with lower surfaces 80a, 82a, and 84a, as seen in FIGS. 3A-3C. By optimization of plating bath chemistry, including the use of additives comprising at least one of a leveler, a suppressor, and an accelerator, the plating bath and conditions may be configured to produce an upper surface 84b, 82b, of the flag 84 and the LGA pads 82, respectively, which is nonconformal with respect to the lower surfaces 84a, and 82a of the flag 84 and the LGA pads 82, as well as nonconformal with respect to the layer of dielectric 70, the conductive layer 60, and the vias 74 formed therein. Nonconformal as used herein refers to structures having a non-uniform thickness across a width or horizontal distance (as depicted in FIGS. 4A, 4B, 5A, 5B, 6A and 6B). Upper surfaces 80b, 82b and 84b which are nonconformal with respect to the dielectric, sidewalls and sidewall angles, conductive layer 60, and lower surfaces 80a, 82a, and 84a are representative of a terminal conductive layer 80, conductive pads or LGA pads 82 and a flag 84 which vary in thickness across a horizontal distance which extends across the layer of dielectric 70 and the vias 74 formed therein. Nonconformal upper surfaces 80b, 82b and 84b are depicted at least in FIGS. 4B, 5B and 6B. Each of these shapes of the upper surfaces may enhance the reliability of solder joints formed during the SMT process, thereby improving package mounting integrity and robustness of the package level interconnections of the QFN, DFN, SON, or LGA package 110 with the terminal conductive layer 80, including the upper surfaces 82b and 84b of the LGA pads 82 and the flag 84.

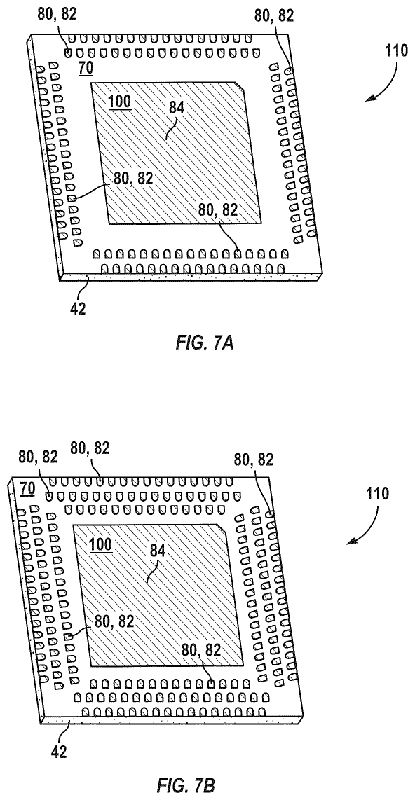

The LGA pads 82 may be formed as a multi-row array or an area array to provide additional connections, including higher-density electrical connections. See, e.g., FIGS. 7A and 7B. The flag 84 provides a thermal and electrical connection point for the package. The electronic assembly or package 110 may further comprise conductive thermal studs 28a formed over the layer of encapsulant 42 and configured to be thermally coupled with the component 14. The thermal studs 28a provide a heat conduction path from the component 14 to an exposed surface of the package, such as the flag 84. This allows heat to be dissipated from the component 14 to the surroundings or ambient environment.

The thermal studs 28a may be formed of copper or other thermally conductive material. They can be formed by a similar process to the electrically conductive studs 28 using deposition, photolithography, and plating. A dielectric material may separate the thermal studs 28a from any electrically conductive studs 28 and traces 60, so as to prevents electrical shorting while still providing a thermal path. In other instances, the thermal studs 28a may directly contact the flag 84. The thermal studs 28a may contact the component 14 directly or through intermediate layers. In some embodiments, the thermal studs 28a only contact dielectric layers over the component 14. By optimizing the number, material, and size of the thermal studs 28a, the thermal performance of the package can be tailored as desired. The thermal studs 28a provide enhanced heat dissipation compared to other packages.

FIG. 3B, continuing from FIG. 3A, is a close-up or enlarged view taken along the section line 3B from FIG. 3A. FIG. 3B illustrates the conductive layer 80 or LGA pad 82 formed over the dielectric layer 70, conformally extending through the via opening 72, disposed over the conductive layer 60, and disposed over the encapsulant 42, forming dimples 90. A maximum dielectric layer thickness, tₘₐₓ, and conductive layer 80 thickness, t_{c}, are further shown. Conductive layer 80 may comprise a thickness, t_{c}, in a range of from about 1 μm to 50 μm, from about 2 μm to 30 μm or from about 2 μm to 10 μm. For high power applications, conductive layer 80 may comprise a thickness, t_{c}, in a range of from about 100 μm to 500 μm or greater.

A solderable metal system (SMS) 100 or an organic solderability preservative (OSP) may be formed or applied over the conductive pads 82 and flag 84. The SMS 100 or OSP resists oxidation and enhances the solderability of the pads 82 and flag 84. The SMS 100 may be formed by electroplating, electroless plating, immersion plating, physical vapor deposition (PVD), chemical vapor deposition (CVD), or any suitable process. These techniques allow the SMS 100 to be selectively deposited on the exposed surfaces of the pads 82 and flag 84. The SMS 100 may comprise a single layer or multi-material layer build-up of conductive materials. For example, the SMS 100 may include layers of nickel (Ni), silver (Ag), palladium (Pd), tin (Sn), and/or gold (Au). The SMS 100 provides a wettable surface for solder attachment. Alternatively, an OSP may be applied to the pads 82 and flag 84 to enhance solderability. The OSP provides a temporary protective coating that prevents oxidation. This allows the pads 82 and flag 84 to be readily soldered. Applying the SMS or OSP 100 improves the connectivity and board level reliability of the QFN, DEN, SON, or LGA package by promoting consistent and high-quality solder joints. The SMS or OSP 100 coats the exposed surfaces of the pads 82 and flag 84 while leaving the dielectric layer 70 uncoated, and can create an electronic assembly 110 without exposed copper.

In some embodiments, organic solderability preservative (OSP) may be used instead of, or in addition to, an SMS to enhance solderability of one or more of the terminal conductive layer 80, the conductive pads 82, and the flag 86, and to resist oxidation over at least a portion of the same. The SMS 100 may comprise a nickel layer 1-2 μm thick, followed by a layer of palladium (Pd) 0.1-. 05 μm thick. Any suitable material may comprise the SMS 100, including one or more layers of Ni, Pd, gold (Au), tin (Sn), solder, silver (Ag), OSP, or other suitable material, forming the SMS as a single or multi-material build-up. The SMS 100 may be formed over a top surface and 4 (or any number) of adjoining side surfaces of the terminal conductive layer 80, the conductive pads 82, and the flag 86. As used herein, the “sides” of the terminal conductive layer 80, the conductive pads 82, and the flag 86 may be any adjoining or adjacent surface, including vertical, sloped, chamfered, or other surfaces.

FIG. 3C, continuing from FIG. 3A, is a cross-sectional perspective view that illustrates the conformal recesses or dimples 90 formed in the conductive pads or terminal conductive layer 80 or LGA pads 82 and the flag 84 that result from a standard HVM Cu plating process.

FIG. 3C further illustrates how the conductive pads 82 and flag 84 may be formed with conformal recesses or dimples 90, in the upper surfaces 80ab, 82ab, and 86b. The dimples 90 comprise concave depressions in the upper surfaces 80ab, 82ab, and 86b that conform to the contours of the dielectric layer 70, conductive layer 60, and vias 74. This conformation occurs due to the plating process used to form the pads 82 and flag 84. However, the dimples 90 can potentially introduce problems with package reliability. During solder reflow, the dimples 90 may trap bubbles that can cause voids in the solder joints which are formed over the LGA pads 82 as part of surface mount technology (SMT) processing to connect the package 110 to a PCB or other structure. Additionally, the dimples 90 may create weak points in the structure of the pads 82 and flag 84. When mechanical or thermal stress is applied, cracks may initiate at features resulting from the dimples 90 resulting in failure of electrical connections. The dimples 90, or features resulting therefrom such as bubbles or voids, can also reduce contact area between the conductive material the structures to which the package 110 is mounted. This decreased adhesion can allow delamination and separation of the pads 82 and flag 84 during temperature cycling and in other instances.

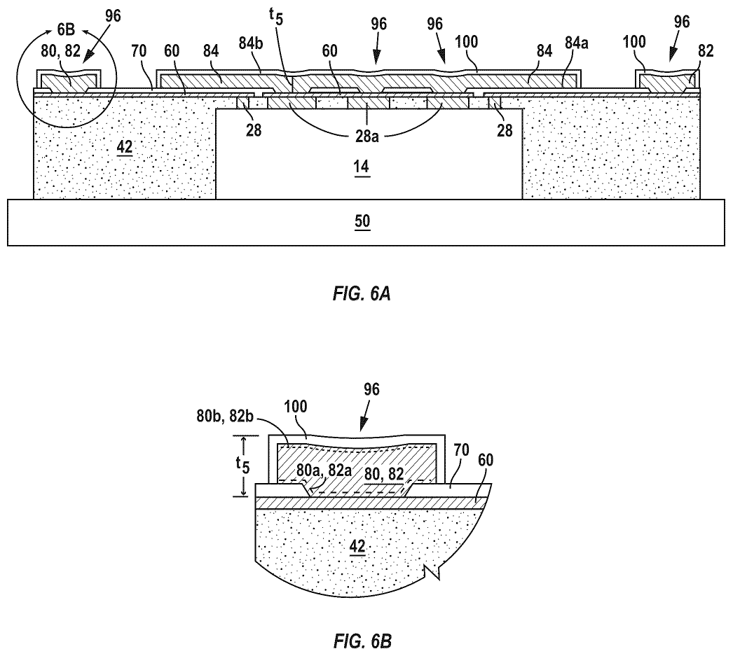

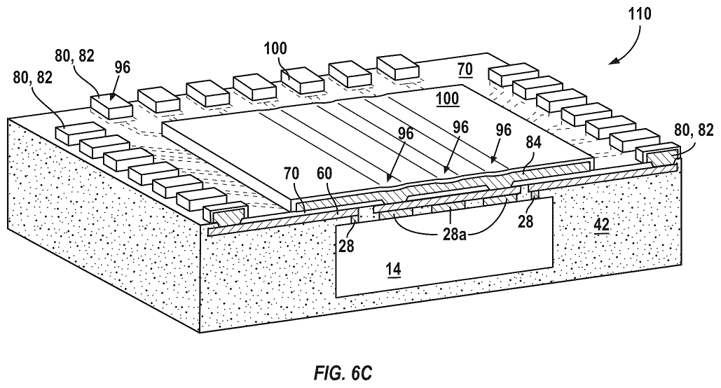

To avoid these potential reliability issues, the plating chemistry and conditions can be optimized to reduce the depth and number of dimples 90. A balance may be found between conformal plating and excessive dimpling. The terminal conductive layer 80 (forming LGA pads 82 and flag 84) may be conformally applied such that lower surfaces 80a, 82a, and 84a and upper surfaces 80b, 82b, and 84b conformally follow the conductive layer 60 or terminal conductive layer 80, the dielectric layer 70, including the via sidewalls and via sidewall angle 76. On the other hand, after optimization of plating chemistry and conditions, the upper surfaces 80b, 82b, and 84b may be nonconformal with respect to the conductive layer 60, the dielectric layer 70, the via sidewalls and via sidewall angle 76, and the lower surfaces 80a, 82a, and 84a. This nonconformity produces upper surfaces 80b, 82b, and 84b comprising a flat surface (see FIGS. 4A-4D), a convex or slightly convex surface (see FIG. 5A-5C), or a slightly concave surface (see FIGS. 6A-6C), to improve or maximize package mounting and increase robustness of interconnections the QFN, DEN, SON, or LGA package 110 with the terminal conductive layer 80, including the LGA pads 82 and the flag 84.

FIG. 4A, continuing from FIG. 2D, is a cross-sectional profile similar to the view of FIG. 3A. FIG. 4A differs from FIG. 3A in that a modified plating process is used, which results in conductive layer or terminal conductive layer 80, land grid array (LGA) pad 82, and flag 84 comprising a flat or level upper surface 80b, 82b, and 84b, respectively, without dimples 90. The plating bath additives may allow the upper surfaces of the terminal conductive layer, the LGA pads and the flag, respectively, 80b, 82b, and 84b to be flatter than the lower surfaces 80a, 82a, and 84a of the terminal conductive layer, the LGA pads and the flag, respectively, as shown in the detail view of FIG. 4B. Specifically, the lower surfaces 80a, 82a, and 84a of the terminal conductive layer 80 are curved to conformally follow the contours of the dielectric layer 70, via openings 72 in the dielectric layer 70, and conductive layer 60. Upper surfaces 80b, 82b, and 84b of the terminal conductive layer 80, the LGA pads and the flag, respectively, are flatter than the lower surfaces 80a, 82a, and 84a of the terminal conductive layer 80, the LGA pads and the flag, respectively. In an embodiment, the terminal conductive layer 80 comprises a flat or substantially flat surface 92 comprising a height difference over an entire horizontal distance of less than or equal to 10 μm. In some instances, a vertical offset of the upper surface 80b of the terminal conductive layer 80 varies by plus or minus 5-10% of a thickness, t_{c}, of the terminal conductive layer 80.

According to some embodiments, the upper surfaces 82b, and 84b of the LGA pads and the flag comprise a flatness with a peak to valley distance less of than half the maximum thickness, tₘₐₓ, of the dielectric layer 70. The peak to valley distance is defined as the vertical distance between the highest and lowest points of a surface. In some instances, the upper surfaces 80b, 82b, and 84b comprising a flat or substantially flat surface 92 may have less than or equal to 10 μm vertical offset over a horizontal or perpendicular distance of 200-400 μm. This allows the LGA pads 82 and flag 84 to make reliable electrical contact through the vias 74 while presenting a flat surface for further connections and for SMT processing. The flat upper surfaces 80b, 82b, and 84b also facilitate the formation of a solderable metal system (SMS) or OSP 100.

As depicted in FIG. 4A, an upper surface 84b of the flag 84 is at a same level as upper surfaces 80b and 82b of the terminal conductive layer 80 and the LGA pads 82, respectively. The terminal conductive layer 80 further comprises lower surfaces 80a, 82a, and 84a that conformally follow contours of the layer of dielectric 70, the vias 74, and the via sidewalls 76 and as such are conformally applied to the layer of dielectric 70, the vias 74, and the via sidewalls 76. The modified plating process comprises electroplating and a plating bath comprising additives, wherein the additives comprise at least one of a leveler additive, a suppressor additive, and an accelerator additive in the plating bath that makes the process adjustable for chemistry to provide more level and planar upper surfaces 80b, 82b, and 84b. In some instances, the additive may be used to provide a tuned deposit morphology for conductive layer 80, land grid array (LGA) pad 82, and flag 84. As a result, the plating chemistry to produce a flat or substantially flat LGA pad, which is preferred for SMT and also removes the dimples 90 that may undesirably be introduced with standard Cu chemistry, results in the structures as shown in FIGS. 4A-4D.

FIG. 4B, continuing from FIG. 4A, is a close-up or enlarged view taken along the section line 4B from FIG. 4A. As depicted in FIGS. 4A and 4B, the nonconformal plating process produces a maximum thickness, t3, of the terminal conductive layer 80, the LGA pads 82 and the flag 84, having flat upper surfaces 92, which is greater than a thickness of the terminal conductive layer 80 produced by a conformal plating process.

FIG. 4C, continuing from FIG. 4A, is a cross-sectional perspective view that illustrates a cross-sectional view similar to that shown in FIG. 4A, and further adds additional detail and form for an entirety of the package 110. FIGS. 4A and 4C illustrate the QFN, DFN, SON, or LGA package 110 further comprising thermal studs 28a disposed between, and coupled to, the component 14 and the flag 84 by way of conductive layer 60. As shown in FIG. 4C and others, the QFN, DEN, SON, or LGA package comprises LGA pads 82 that may be non-spherical in form and may comprise a variety of shapes, such as spherical, circular, oval, rectangular, square, polygonal and others, without limitation.

FIG. 4D, similar to FIG. 4C, is a cross-sectional perspective view that illustrates an embodiment in which the package 110 may be formed without thermal studs 28a disposed between, and coupled to, the component 14 and the flag 84. FIGS. 4C and 4D further illustrate a perspective view of LGA pads 82 and flag 84 having flat surfaces 92.

FIG. 5A, continuing from FIG. 2D, is another cross-sectional profile similar to the views of FIG. 4A. FIG. 5A differs from FIG. 4A in that a modified plating process is used, which results in conductive layer 80, land grid array (LGA) pad 82, and flag 84 comprising a convex or slightly convex upper surface 80b, 82b, and 84b, respectively, without dimples 90. The lower surfaces 80a, 82a, and 84a are conformally applied to the layer of dielectric 70, the conductive layer 60, and the via openings 72.

FIG. 5B, continuing from FIG. 5A, is a close-up or enlarged view taken along the section line 5B from FIG. 5A, where analogous structures are referred to by like reference numbers as included in FIG. 4B. As depicted in FIGS. 5A and 5B, the nonconformal plating process produces a maximum thickness, t4, of the terminal conductive layer 80, the LGA pads 82 and the flag 84, having convex or slightly convex upper surfaces 94, which is greater than a thickness of the terminal conductive layer 80 produced by a conformal plating process.

FIG. 5C, continuing from FIG. 5A, is a cross-sectional perspective view that illustrates a cross-sectional view similar to that shown in FIG. 4A, and further adds additional detail and form for an entirety of the package 110. FIG. 5C further illustrates a perspective view of LGA pads 82 and flag 84 having convex or slightly convex surfaces 94.

FIG. 6A, continuing from FIG. 2D, is another cross-sectional profile similar to the views of FIG. 4A. FIG. 6A differs from FIG. 4A in that a modified plating process is used, which results in conductive layer or terminal conductive layer 80, land grid array (LGA) pad 82, and flag 84 comprising a concave or slightly concave shape 96 of upper surface 80b, 82b, and 84b, respectively, but without dimples 90 through control of the plating bath chemistry and process conditions. The lower surfaces 80a, 82a, and 84a may be conformally applied to the layer of dielectric 70, the via openings 72 and the conductive layer 60.

FIG. 6B, continuing from FIG. 6A, is a close-up or enlarged view taken along the section line 5B from FIG. 6A, where analogous structures are referred to by like reference numbers as included in FIGS. 4B and 5B. As depicted in FIGS. 6A and 6B, the nonconformal plating process produces a maximum thickness, t5, of the terminal conductive layer 80, the LGA pads 82 and the flag 84, having concave or slightly concave upper surfaces 96, which is greater than a thickness of the terminal conductive layer 80 produced by a conformal plating process.

FIG. 6C, continuing from FIG. 6A, is a cross-sectional perspective view that illustrates a cross-sectional view similar to that shown in FIG. 4A, and further adds additional detail and form for an entirety of the package 110. As seen in FIG. 6C, thermal studs 28a may be formed along a length of component 14 as a trough or channel-like structure, thereby producing a flag 84 having concave or slightly concave surfaces 96 comprising a trough or channel like shape extending along a length of an upper surface 84b of flag 84. FIG. 6C further illustrates a perspective view of LGA pads 82 having a concave or slightly concave surface 96.

FIGS. 7A and 7B illustrate instances in which the QFN, DEN, SON, or LGA package or electronic assembly 110 can comprise LGA pads 82 formed as multi-row LGA pads or an array of LGA pads, further comprising a flag 84. FIG. 7A illustrates two rows of LGA pads 82 and FIG. 7B illustrates three rows of LGA pads 82.

FIGS. 8A and 8F illustrate instances in which the electronic assembly 110 may comprise one or more layers, including multiple layers, of encapsulant 42, internal conductive layers 60, and layers of dielectric 70. FIG. 8A illustrates the electronic assembly 110 comprising a multi-layer stack with the first internal conductive layer 60 disposed over, and in direct contact with, the encapsulant 42.

FIG. 8B illustrates another embodiment of the electronic assembly 110 comprising a multi-layer stack, wherein a layer of dielectric 70 is formed between the first internal conductive layer 60 and the encapsulant 42. In some instances, when dielectric layer 70 is formed as a solder mask or other material that comprises a CTE or other material property that creates undesired stress or asymmetrical forces on the assembly 110, an additional backside layer 70 may be formed over the backside of the assembly 110 to balance the forces applied by the dielectric layer 70 to the assembly 110. In some instances, one or more of the dielectric layers 70 may be formed as a security material, so if one attempts to get into the device with force, the device self-destructs or become inoperable. In other words, the dielectric layer 70 may comprise a tamper resistant material, such as a flame sprayed material, a flame sprayed metallic material, or other suitable security coating. FIGS. 8A and 8B further illustrate vias 74 aligned vertically in a stacked configuration.

FIG. 8C illustrates additional detail of a portion of the electronic assembly 110 comprising a multi-layer stack, with a close-up cross-sectional view taken along the line 8C shown in FIG. 8B. As shown, vias 74 may be formed within via openings 72 in dielectric 70 between conductive layers 60 according to the “via last” structure 78 (as also shown in FIG. 8F).

FIG. 8D illustrates the electronic assembly 110 comprising a multi-layer stack in a sandwich configuration, with upper and lower dielectric layers 70, and one or more layers of encapsulant 42 disposed therebetween.

FIG. 8E illustrates the electronic assembly 110 comprising a multi-layer stack in another sandwich configuration, with upper and lower encapsulant layers 42, with one or more dielectric layers 70, disposed therebetween. FIG. 8E further illustrates vias 74 aligned vertically in a stacked via configuration.

FIG. 8F illustrates a close-up view of a portion of the electronic assembly 110 comprising a multi-layer stack and relative sidewall angles for vias 74, conductive studs 28, 28a and conductive stumps 29. According to an embodiment, a conductive stump 29, thermal stud 28a, or conductive stud 28, formed in a via first process 34, with encapsulant 42 disposed around the conductive stump 29, thermal stud 28a, or conductive stud 28, is shown to have a sidewall angle 29a in a range of about 80-90°, or 85-90°. In some embodiments, a via 74 formed in a via last process 78 within the dielectric layer 70 is shown to have a sidewall angle 76 in a range of about 45-90°, or 70-89°, or an angle less than the sidewall angle 29a of the via first process 34.

FIG. 9 illustrates instances in which the package or electronic assembly 110 is formed using unit-specific patterning (also known under the tradename Adaptive Patterning™) such that a position of the flag 84 and an outline 86 of the flag 84 aligns more closely to an outline 112 of the package 110 than to an outline 15 of the component 14 or to an outline 15 of the molded component 44. Similarly, a position of the LGA pad 82 is determined with unit-specific patterning such that an outline 83 of LGA pad 82 aligns more closely to an outline 112 of the package 110 than to an outline 15 of the component 14. Similarly, unit-specific patterning produces for a package outline angle 112a which is the same as, or substantially the same as, a flag outline angle 86a, where each of the package outline angle 112a and flag outline angle 86a differ from a component outline angle 15a, as depicted in FIG. 9.

While this disclosure includes a number of embodiments in different forms, there is presented in the drawings and written descriptions in the following pages detail of particular embodiments with the understanding that the present disclosure is to be considered as an exemplification of the principles of the disclosed methods and systems, and is not intended to limit the broad aspect of the disclosed concepts to the embodiments illustrated. Additionally, it should be understood by those of ordinary skill in the art that other structures, manufacturing devices, and examples could be intermixed or substituted with those provided. In places where the description above refers to particular embodiments, it should be readily apparent that a number of modifications may be made without departing from the spirit thereof and that these embodiments and implementations may be applied to other technologies as well. Accordingly, the disclosed subject matter is intended to embrace all such alterations, modifications and variations that fall within the spirit and scope of the disclosure and the knowledge of one of ordinary skill in the art. As such, it will be evident that various modifications and changes may be made thereto without departing from the broader spirit and scope of the disclosure as set forth in the appended claims. The specification and drawings are, accordingly, to be regarded in an illustrative sense rather than a restrictive sense.

What is claimed is:

1. A quad flat no-lead (QFN), dual flat no-lead (DFN) or small outline no-lead (SON) package without a leadframe, comprising:
a component comprising conductive studs disposed over an active layer of the component;
a single layer of encapsulant disposed around four side surfaces of the component, disposed over the active layer of the component, and contacting at least a portion of sidewalls of the conductive studs;
a flat surface, comprising a flat encapsulant surface and exposed ends of the conductive studs, disposed over the active layer of the component and around a periphery of the exposed ends;
an internal conductive layer disposed over the flat surface and configured to be electrically coupled with the conductive studs to fan-out from the component;
a layer of dielectric disposed over the flat surface and the internal conductive layer;
via openings formed through the layer of dielectric that extend to the internal conductive layer; and
a flag and land grid array (LGA) pads formed as part of a terminal conductive layer disposed over the layer of dielectric, wherein the flag and LGA pads extend through the via openings and contact the internal conductive layer, wherein an upper surface of the flag is at a same level as an upper surface of the LGA pads.

2. The package of claim 1, wherein the flag and the LGA pads each comprise a lower surface that is curved to conformally follow contours of the layer of dielectric and the via openings, wherein the terminal conductive layer further comprises an upper surface that is flatter than the lower surface.

3. The package of claim 2, wherein the upper surfaces of the flag and the LGA pads comprise a flatness with a peak to valley distance of less than half a thickness of a maximum thickness of the dielectric layer.

4. The package of claim 1, wherein the upper surface of the terminal conductive layer comprises less than or equal to 10 μm of height difference over an entire horizontal distance.

5. The package of claim 1, further comprising thermal studs disposed between, and coupled to, the component and the flag.

6. The package of claim 1, wherein:
the conductive stud comprises a sidewall angle in a range of 80-90°; and
the via openings comprises a sidewall angle in a range of 70-89°.

7. The package of claim 1, wherein a position of the LGA pad is determined with unit-specific patterning such that an outline of LGA pad aligns more closely to an outline of the package than to an outline of the component.

8. The package of claim 1, wherein the internal conductive layer is disposed over the flat surface and configured to be electrically coupled with the conductive studs to fan-out from the component.

9. The package of claim 1, wherein an upper surface of the terminal conductive layer comprises a flat surface, a slightly domed surface, or a slightly concave surface.

10. The package of claim 1, wherein a vertical offset of the upper surface of the terminal conductive layer varies plus or minus 5-10% of a thickness of the terminal conductive layer.

11. The package of claim 1, wherein the LGA pads are non-spherical in form.

12. A quad flat no-lead (QFN), dual flat no-lead (DFN) or small outline no-lead (SON) package without a leadframe, comprising:
a component comprising conductive studs disposed over a surface of the component;
a single layer of encapsulant disposed around four side surfaces of the component and around at least a portion of the conductive studs;
a layer of dielectric disposed over the single layer of encapsulant with via openings formed through the layer of dielectric; and
a terminal conductive layer disposed over the layer of dielectric, the terminal conductive layer further comprising a lower surface that conformally follows contours of the layer of dielectric and the via openings, wherein the terminal conductive layer further comprises an upper surface that is flatter than the lower surface.

13. The package of claim 12, wherein the terminal conductive layer further comprises land grid array (LGA) pads.

14. The package of claim 13, wherein the terminal conductive layer further comprises a flag with an upper surface at a same level as an upper surface of the LGA pads.

15. The package of claim 12, wherein the conductive studs comprises a sidewall angle that is substantially vertical and a via formed in the via openings comprises a sidewall angle less than the sidewall angle of the conductive stud.

16. The package of claim 12, wherein the single layer of encapsulant is a material suitable for planarizing, such as with grinding or chemical mechanical planarizing (CMP).

17. The package of claim 13, wherein a position of the LGA pads is determined with unit-specific patterning such that an outline of the LGA pads aligns more closely to an outline of the package than to an outline of the component.

18. The package of claim 12, wherein the upper surface of the terminal conductive layer comprises a flat surface, a slightly domed surface, or a slightly concave surface.

19. The package of claim 12, wherein a vertical offset of the upper surface of the terminal conductive layer varies by plus or minus 5-10% of a thickness of the terminal conductive layer.

20. The package of claim 14, wherein the upper surface of the flag and the LGA pads is nonconformal with respect to the layer of dielectric, an internal conductive layer, and the via openings.
